(19) United States
(12) Patent Application Publication
(10) Pub. No.: US 2025/0391765 A1
(43) Pub. Date: Dec. 25, 2025

(54) Metallic Structure, Method of Preparing Same, and Electronic Device Including Same

(71) Applicant: SAMSUNG ELECTRONICS CO., LTD., Suwon-si (KR)

(72) Inventors: Youngchul Leem, Suwon-si (KR); Young Min Lee, Suwon-si (KR); JEONGYUB LEE, Suwon-si (KR); Eun-Hyoung CHO, Suwon-si, Gyeonggi-do (KR)

(21) Appl. No.: 19/244,430

(22) Filed: Jun. 20, 2025

(30) Foreign Application Priority Data
Jun. 19, 2024 (KR) 10-2024-0079932

(51) Int. Cl. H01L 23/522; C23C 16/04; C23C 16/18; C23C 16/56; H01L 21/768; H01L 23/532

(52) U.S. Cl. CPC H01L 23/5228; C23C 16/045; C23C 16/18; C23C 16/56; H01L 21/76844; H01L 21/76879; H01L 23/5226; H01L 23/53266

(57) ABSTRACT

A metallic structure, a method of preparing the metallic structure, and the electronic device including the metallic structure. The metallic structure includes a ruthenium (Ru) thin film disposed on an insulation film or a contact metal, where the ruthenium thin film has a crystal structure including grains having a (001) orientation, neighboring grains among the grains in the thin film have a misorientation angle of less than or equal to about 15° at a grain boundary based on a horizontal direction of the thin film.

### CROSS-REFERENCE TO RELATED APPLICATION

This application is based on and claims priority to Korean Patent Application No. 10-2024-0079932 filed with the Korean Intellectual Property Office on Jun. 19, 2024, and all the benefits accruing therefrom under 35 U.S.C. § 119, the content of which is incorporated herein in its entirety by reference.

### BACKGROUND

### 1. Field

A metallic structure, a method of preparing the metallic structure, and an electronic device including the metallic structure are disclosed.

### 2. Description of the Related Art

In order to provide high-density, high-performance semiconductor devices, efforts are continuing to reduce the line width or thickness of a metal wire in the continuing effort to scale down electronic devices and also address resistivity increase challenges. If the line width or thickness of the metal wire is reduced, the number of semiconductor chips integrated per wafer may be increased, and in addition, line capacitance may be reduced, which may increase a speed of signals through the wire.

However, if the line width or thickness of the metal wire is reduced, there may be a problem of rapidly increasing resistance, and in addition, deterioration due to oxidation at the interface between metal and oxide or at the exposed surface of the metal may occur.

Accordingly, a wire material capable of reducing the resistance of a wire structure, preventing the deterioration due to oxidation, and implementing excellent electrical characteristics is desired.

### SUMMARY

An embodiment provides a metallic structure that has excellent electrical characteristics due to a low rate of increase in resistance as a result of a decrease in line width and which also may be prepared at a low process temperature using a simplified process.

Another embodiment provides a method of preparing the metallic structure.

Another embodiment provides an electronic device including the metallic structure.

A metallic structure according to an embodiment includes a ruthenium (Ru) thin film disposed on an insulation film or a contact metal, wherein the ruthenium thin film has a crystal structure including grains having a (001) orientation, and neighboring or adjacent grains among the grains in the ruthenium thin film have a misorientation angle of less than or equal to about 15° at a grain boundary based on a horizontal direction of the ruthenium thin film, thereby forming the metallic structure.

The ruthenium thin film may have a ratio {(002)/(101)} of an intensity of a (002) peak to an intensity of a (101) peak observed by X-ray diffraction (XRD) analysis of greater than or equal to about 30.

The ruthenium thin film may have a Rotgering degree of orientation of greater than or equal to about 99% for a (002) plane as observed by XRD analysis.

The ruthenium thin film may have a resistivity of less than or equal to about 10 microohm-centimeters (μΩ·cm) at a thickness of 10 nanometers (nm).

The insulation layer may include aluminum oxide AlO_{z} (0<z≤3/2), aluminum nitride (AlN), zirconium oxide (ZrOₓ) (0<x≤2), hafnium oxide (HfOₓ) (0<x≤2), silicon oxide (SiO₂), silicon nitride (SiN), silicon oxynitride (SiON), silicon carbonitride (SiCN), silicon carbonate nitride (SiCON), or a combination thereof.

The contact metal may include copper (Cu), aluminum (Al), ruthenium (Ru), cobalt (Co), tungsten (W), molybdenum (Mo), or a combination thereof.

The metallic structure may further include a deposition-inhibiting layer, a barrier layer, a liner layer, or a combination thereof between the insulation film and the ruthenium thin film.

A method of preparing a metallic structure according to another embodiment includes depositing a precursor including ruthenium on an insulation film or a contact metal, together with an oxidizing agent, a reducing agent, or a combination thereof, at a process pressure of less than or equal to about 10 Torr and a process temperature of less than or equal to about 550° C. by an atomic layer deposition (ALD) or chemical vapor deposition (CVD) method to form a ruthenium thin film, wherein the formed ruthenium thin film has a crystal structure including grains having a (001) orientation, and neighboring or adjacent grains among the grains in the ruthenium thin film have a misorientation angle of less than or equal to about 15° at a grain boundary based on a horizontal direction of the ruthenium thin film, thereby forming the metallic structure.

The process temperature may be less than or equal to about 450° C.

The precursor including the ruthenium may include (ethylbenzene)(1-ethyl-1,4-cyclohexadiene)Ru(0), (1-isopropyl-4-methylbenzene)(1,3-cyclohexadiene)Ru(0), (benzene)(1,3,5-cycloheptatriene)Ru(0), (2,3-dimethyl-1,3-butadieneL)Ru(0)tricarbonyl, (1,3-cyclohexadiene)Ru(0)tricarbonyl, (1,3,5-cycloheptatriene)Ru(0)tricarbonyl, (cyclopentadienyl)(ethyl)Ru(II)dicarbonyl, bis(ethylcyclopentadienyl)Ru(II), (2,4-dimethylpentadienyl)(ethylcyclopentadienyl)Ru(II), bis(2,4-dimethylpentadienyl)Ru(II), bis(2,4-pentanediketonato)Ru(II)dicarbonyl, (N,N′-di-isopropylacetamidinato)Ru(II)dicarbonyl, or a combination thereof.

The oxidizing agent may include a plasma species generated from oxygen (O₂), ozone (O₃), water (H₂O), or a combination thereof.

The reducing agent may include a plasma species generated from hydrogen (H₂), ammonia (NH₃), or a combination thereof.

The method may further include annealing at a temperature of less than or equal to about 550° C., for example, less than or equal to about 450° C. after depositing the ruthenium thin film.

The method may further include patterning the formed ruthenium thin film after forming the ruthenium thin film.

The method may further include forming an upper electrode on the formed ruthenium thin film.

The method may further include forming an additional insulation film including a trench on the insulation film or contact metal before depositing the ruthenium thin film.

The method may further include forming a deposition-inhibiting layer, a barrier layer, a liner layer, or a combination thereof on an inner surface of the trench, on an upper portion of the additional insulation film, or on both of the inner surface of the trench and the upper portion of the additional insulation film, after forming the trench, and before depositing the ruthenium thin film.

The ruthenium thin film may be deposited within the trench. In another embodiment, an electronic device includes a metallic structure according to an embodiment.

The electronic device includes a logic device, a memory device, or a non-memory device.

A metallic structure according to an embodiment has excellent electrical characteristics due to a low rate of increase in resistance as a result of a decrease in line width, and may be prepared at a low process temperature using a simplified process. Accordingly, the metallic structure according to an embodiment may be advantageously used as an upper via or upper metal wire of various electronic devices requiring high integration.

### BRIEF DESCRIPTION OF THE DRAWINGS

FIG. 1 is a graph showing the resistivities (ohm-nanometers, Ω·m) of copper (Cu), ruthenium (Ru), and cobalt (Co) as a function of the critical dimension (CD) (nanometers, nm) of the filling metal.

FIG. 2 is a graph comparing the resistivities (ohm-nanometers, Ω·m) of copper (Cu), ruthenium (Ru), and cobalt (Co) as a function of the critical dimension (CD) (nanometers, nm) of the filling metal, where cobalt (Co) including a titanium nitride (TiN) barrier metal layer or not including a barrier; ruthenium (Ru) not including a barrier; and cupper (Cu) including a manganese ruthenium (MnRu) barrier metal layer, a tantalum nitride ruthenium (TaNRu) barrier metal layer, or a tantalum nitride cobalt (TaNCo) barrier metal layer.

FIG. 3A is an XRD normal mode graph showing intensity (arbitrary unit, a.u.) versus 2 Theta (degree, °) of a ruthenium (Ru) thin film prepared by a conventional ALD method.

FIG. 3B is a glancing angle XRD (b) graph showing intensity (arbitrary unit, a.u.) versus 2 Theta (degree, °) of a ruthenium (Ru) thin film prepared by a conventional ALD method.

FIG. 3C shows surface (left) and cross-sectional (right) images of a ruthenium (Ru) thin film prepared by a conventional ALD method, as measured by a scanning electron microscope (SEM).

FIG. 3D is a schematic view showing the orientation of crystal grains in a ruthenium (Ru) thin film prepared by a conventional ALD method.

FIG. 4A is an XRD normal mode graph showing intensity (arbitrary unit, a.u.) versus 2 Theta (degree, °) of a ruthenium (Ru) thin film in a metallic structure according to an embodiment.

FIG. 4B is an XRD normal mode graph showing intensity (arbitrary unit, a.u.) versus 2 Theta (degree, °) of FIG. 4A in a semi-log scale.

FIG. 4C is a glancing angle XRD graph showing intensity (arbitrary unit, a.u.) versus 2 Theta (degree, °) of a ruthenium (Ru) thin film in a metallic structure according to an embodiment.

FIG. 4D is a surface (left) and cross-sectional (right) image of a ruthenium (Ru) thin film in a metallic structure according to an embodiment, measured by SEM.

FIG. 4E is a schematic view illustrating the orientation of crystal grains in a ruthenium (Ru) thin film in a metallic structure according to an embodiment.

FIG. 5 shows selected area electron diffraction (SAED) patterns measured by transmission electron microscopy (TEM) of a ruthenium (Ru) thin film formed by conventional sputtering and thermal curing (a), and a ruthenium (Ru) thin film in a metallic structure according to an embodiment (b).

FIG. 6 shows high-resolution transmission electron microscopy (HRTEM) images, and fast Fourier transform (FFT) images obtained therefrom of a ruthenium (Ru) thin film formed by conventional sputtering and thermal curing (a), and a ruthenium (Ru) thin film in a metallic structure according to an embodiment (b).

FIG. 7 schematically illustrates a case where metal crystal grains forming a narrow-width wire have a strong vertical orientation but inferior horizontal orientation (a), and a case where both vertical and horizontal orientations are excellent (b).

FIG. 8 is a graph showing the change in resistivity (microohm-centimeters, μΩ·cm) according to the thickness (angstrom, Å) of a ruthenium (Ru) thin film included in a metallic structure according to an embodiment.

FIG. 9 is a schematic view illustrating a cross-section of an electronic device in which a metallic structure according to an embodiment is implemented as an upper via or upper metal wire of a three-dimensional logic device.

FIG. 10 is a process view schematically illustrating a method of implementing a metallic structure with an upper via or upper metal wire according to an embodiment.

FIG. 11 is a process view schematically illustrating another method of implementing a metallic structure with an upper via or upper metal wire according to an embodiment.

### DETAILED DESCRIPTION

Hereinafter, example embodiments of the present disclosure will be described in detail so that a person skilled in the art would understand the same. This disclosure may, however, be embodied in many different forms and is not construed as limited to the example embodiments set forth herein.

The terminology used herein is used to describe embodiments only, and is not intended to limit the present disclosure.

As used herein, the singular forms “a,” “an,” and “the” are intended to include the plural forms, including “at least one,” unless the content clearly indicates otherwise. Therefore, reference to “an” element in a claim followed by reference to “the” element is inclusive of one element as well as a plurality of the elements.

“At least one” is not to be construed as limiting “a” or “an.” “Or” means “and/or.” As used herein, the term “and/or” includes any and all combinations of one or more of the associated listed items.

It will be further understood that the terms “comprises” and/or “comprising,” or “includes” and/or “including” when used in this specification, specify the presence of stated features, regions, integers, steps, operations, elements, and/or components, but do not preclude the presence or addition of one or more other features, regions, integers, steps, operations, elements, components, and/or groups thereof.

Furthermore, relative terms, such as “lower” or “bottom” and “upper” or “top,” may be used herein to describe one element's relationship to another element as illustrated in the Figures. It will be understood that relative terms are intended to encompass different orientations of the device in addition to the orientation depicted in the Figures. For example, if the device in one of the figures is turned over, elements described as being on the “lower” side of other elements would then be oriented on “upper” sides of the other elements. The exemplary term “lower,” can therefore, encompasses both an orientation of “lower” and “upper,” depending on the particular orientation of the figure. Similarly, if the device in one of the figures is turned over, elements described as “below” or “beneath” other elements would then be oriented “above” the other elements. The exemplary terms “below” or “beneath” can, therefore, encompass both an orientation of above and below.

In the drawings, the thickness of layers, films, panels, regions, etc., are exaggerated for clarity. Like reference numerals designate like elements throughout the specification. It will be understood that when an element such as a layer, film, region, or substrate is referred to as being “on” another element, it can be directly on the other element or intervening elements may also be present. In contrast, when an element is referred to as being “directly on” another element, there are no intervening elements present.

Thus, herein, the terms “on” or “upper” may include not only things that are directly above, below, left, or right in contact, but also things that are non-contacting above, below, left, or right.

The term “layer” includes a construction having a shape formed on a part of a region, in addition to a construction having a shape formed on an entire region.

As used herein, the term “the” or similar indicative terms correspond to both the singular form and the plural form. The steps of all methods described herein can be performed in any suitable order unless otherwise indicated herein or otherwise clearly contradicted by context.

In addition, terms such as “. . . unit” and “module” used in the specification refer to a unit that processes at least one function or operation, which may be implemented as hardware or software, or as a combination of hardware and software.

The connections or connection members of lines between components shown in the drawings exemplify functional connections and/or physical or circuit connections, and in actual devices, may be represented as various functional connections, physical connections, or circuit connections.

As used herein, “at least one of A, B or C,” “one of A, B, C, or a combination thereof” and “one of A, B, C, and a combination thereof” refer to each component and refers to any combination (e.g., A; B; C; A and B; A and C; B and C; or A, B, and C).

Here, “a combination thereof” means a mixture of components, a laminate, a composite, an alloy, a blend, and the like.

In this specification, “greater than or equal to” or “less than or equal to” in a numerical range refers to a range that includes the indicated value, and the numerical range may also include a range that combines the indicated ranges.

Herein, unless otherwise defined, “substantially” or “approximately” or “about” includes not only the stated value, but also the average within an allowable range of deviation, considering the error associated with the measurement and amount of the measurement. For example, “substantially” or “approximately” may mean within ±10%, ±5%, ±3%, or ±1% of the indicated value or within a standard deviation.

Unless otherwise defined, all terms (including technical and scientific terms) used herein have the same meaning as commonly understood by one of ordinary skill in the art to which this disclosure belongs. It will be further understood that terms, such as those defined in commonly used dictionaries, should be interpreted as having a meaning that is consistent with their meaning in the context of the relevant art and the present disclosure, and will not be interpreted in an idealized or overly formal sense unless expressly so defined herein.

Exemplary embodiments are described herein with reference to cross section illustrations that are schematic illustrations of idealized embodiments. As such, variations from the shapes of the illustrations as a result, for example, of manufacturing techniques and/or tolerances, are to be expected. Thus, embodiments described herein should not be construed as limited to the particular shapes of regions as illustrated herein but are to include deviations in shapes that result, for example, from manufacturing. For example, a region illustrated or described as flat may, typically, have rough and/or nonlinear features. Moreover, sharp angles that are illustrated may be rounded. Thus, the regions illustrated in the figures are schematic in nature and their shapes are not intended to illustrate the precise shape of a region and are not intended to limit the scope of the present claims.

Herein, “metal” is interpreted as a concept including metals and metalloids (semi-metals).

Hereinafter, a metallic structure according to an embodiment is further described.

Currently, the most widely used material as a metal wire material for semiconductor devices and the like is copper. In particular, copper may be used even in a wire structure with a line width of about 10 nm by a damascene process of filling copper through electroplating. However, because copper may be diffused into insulation film materials such as silicon, silicon dioxide, and the like, the copper diffusion must be prevented by forming a barrier layer, a liner layer, a metal cap, or the like. The barrier layer or the liner layer may reduce an effective cross-section of the metal wire, and accordingly, the copper line may have higher effective resistance than a barrier-less copper line.

The resistance increased due to the barrier may be significantly further increased, as the width of the metal wire is reduced. According to Matthiessen's law, line resistivity is composed of bulk resistivity, impurity scattering, surface scattering, grain boundary (GB) scattering), and the like. In technologies prior to a line width of about 7 nanometers (nm), the line resistivity was in general determined by the bulk resistivity and impurity scattering. However, the surface scattering and the grain boundary scattering have become increasingly important. Surface scattering is essentially required of minimizing a volume ratio of copper reduced by the barrier and the liner, and the grain boundary scattering is affected by the interface and a grain size of the copper.

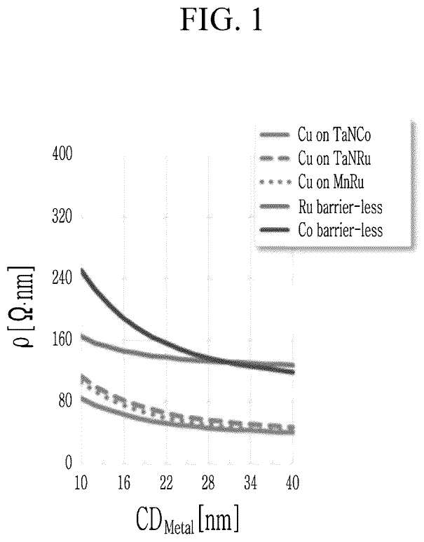

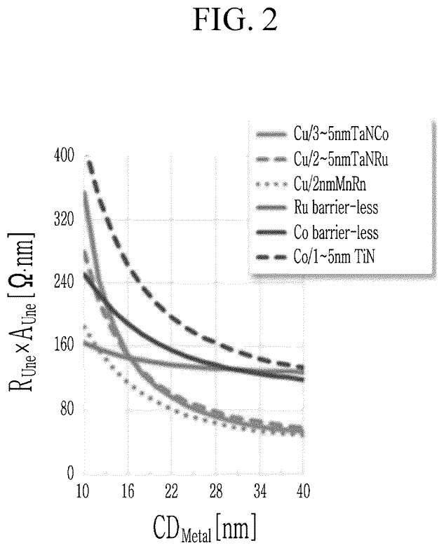

If the filling metal has an aspect ratio of about 2, copper (Cu), ruthenium (Ru), and cobalt (Co) have a resistivity shown in FIG. 1, as a function of critical dimension (CD) or line width of the filling metal. The resistivity of copper (Cu) may vary with a barrier metal layer, such as, tantalum nitride cobalt (TaNCo), manganese ruthenium (MnRu), or tantalum nitride ruthenium (TaNRu), which is caused by a different grain size and electron scattering due to different barrier processes. As for the alternative metals, resistivity of ruthenium (Ru) increases slowly with scaling due to a small effect of the electron scattering at the interface, and the resistivity of Ru crossovers with that of Co at a critical dimension (CD) of about 30 nm. However, at a metal critical dimension (CD) of at least about 10 nm, no crossover between ruthenium (Ru) and cobalt (Co) occurs. Accordingly, copper outperforms ruthenium and cobalt in resistivity for the same filler metal cross-section. However, the resistance comparison should be performed for the same trench cross-section, but if considering the presence of the barrier, the effective cross-section of copper is substantially reduced. This is illustrated in FIG. 2.

As shown in FIG. 2, ruthenium (Ru) and cobalt (Co) with no barrier outperforms copper (Cu) at narrow pitches, wherein the ruthenium (Ru) has a first crossover with the copper (Cu) at critical dimension (CD) of about 16 nm, and the cobalt (Co) has a first crossover with the copper (Cu) at critical dimension (CD) of about 12 nm. The reason is that the ruthenium (Ru) and cobalt (Co) need no barrier with high resistance, which leads to relative overcompensation by a larger cross-section that can be used in a trench. As for the oxides, because cobalt (Co) requires a diffusion barrier, cobalt (Co) with a 1.5 nm titanium nitride (TiN) barrier, as shown in FIG. 2, has no wire resistance advantage over copper (Cu) but rather has a disadvantage.

The search for new metallic materials used for a metallic structure, for example, for an interconnect structure and the like is of interest due to concerning behaviors of copper (Cu) at a small critical dimension (CD). Initially, the focus concerned pure metals, the simplest conductors. Co (cobalt), Ru (ruthenium), Rh (rhodium), Ir (iridium), Mo (molybdenum), and the like have been expected to have better electrical characteristics than copper (Cu), but these alternative materials have higher resistance than copper (Cu) at larger critical dimensions (CD). However, if the dimensions of a wire (interconnect) become smaller, the resistance slowly increases, so these alternative materials have better prospects at the smaller dimensions. However, when considering the cost of raw materials, an environmental impact, and the like, some of the above materials may not provide good results, but molybdenum (Mo) and ruthenium (Ru) are being considered as possible materials.

As a method of forming the metal wire or the metallic structure, various thin film deposition processes such as physical vapor deposition (PVD), chemical vapor deposition (CVD), electroplating, and the like may be used. The PVD method is known to be able to produce a metal thin film with higher purity and lower resistivity than the CVD method or electroplating method. The reason is that a metal thin film formed by using a chemical precursor may include a large amount of impurities (carbon (C), hydrogen (H), oxygen (O), and the like), which may increase resistivity of a metal wire finally formed therewith.

Accordingly, the PVD method including a sputtering method is adopted to form a high-quality low-resistivity ruthenium (Ru) thin film. The ruthenium (Ru) thin film formed through the corresponding method have a grain size difference depending on thickness. Because the ruthenium (Ru) thin film is composed of small particles due to particle formation according to a thickness, such a thin ruthenium (Ru) film, even if a post-annealing process is included, is significantly limited in aggregation of the particles and reduction in the resistivity, resultantly exhibiting a very small improvement effect. Accordingly, the corresponding study proposes a method of forming a 135 nm-thick thin film to enhance its (001) orientation, and then, performing post annealing and etch-back to form a high-quality ruthenium (Ru) thin film (IEEE Electron Device let., 2019, 40, 91/DOI: 10.1109/LED.2018.2879932). However, this method results in much material loss and requires a long process time, and thus is difficult to implement in practice.

Another method for implementing a high-quality ruthenium (Ru) thin film is known, which uses a monocrystalline substrate, for example, a sapphire substrate, a magnesium oxide (MgO) substrate, or the like, or a monocrystalline seed layer (a seed layer), for example, silicon dioxide (SiO₂), and then a graphene layer deposited thereon through epitaxy (ACS Appl. Electron. Mater. 2022, 4, 12, 5775/DOI:10.1021/acsaelm.2c00963). However, the corresponding method requires a deposition temperature of about 600° C. to form monocrystalline hexagonal close-packed (HCP) ruthenium (Ru) and subsequent heat treatment temperature of about 1000° C. Th corresponding method may provide a ruthenium (Ru) thin film with resistivity of about 12 μΩ·cm at a thickness of about 10 nm. However, the seed layer, monocrystalline substrate, and high temperature formation methods have many limitations in applying to actual devices.

However, a recent study has also been published, in which a ruthenium (Ru) precursor, Ru(TMM)(CO)₃, and oxygen (O₂) molecules are sequentially supplied onto a SiO₂ substrate through ALD (Atomic-Layer Deposition) to deposit a ruthenium (Ru) thin film (Chem. Mater. 2021, 33, 14, 5639/DOI: 10.1021/acs.chemmater.1c01054). The method proposes a method of depositing a highly crystalline HCP-Ru film having a thickness of about 1.7 Å per cycle on the substrate at a relatively low deposition temperature of about 220° C., a relatively high average grain size, and negligible impurities. In addition, provided is a metal film with resistance of about 12.9 μΩ·cm (at a thickness of about 40 nm) at a temperature of about 260° C. The film has a resistivity reduced to about 9.8 μΩ·cm after post-annealing at about 500° C. due to high interfacial adhesion energy.

Another study (Nano Lett. 2022, 22, 11, 4589/DOI: 10.1021/acs.nanolett.2c00811) proposes a method for depositing an ultrathin continuous ruthenium (Ru) film in a discrete feeding-ALD (DF-ALD) method. This method improves surface coverage of the precursor by using cut-in purge while supplying the precursor and growth behavior of the film in the early growth stage. The surface coverage of the precursor may increase nucleation density, which may increase nuclear formation density, and in turn, lead to a smaller grain size. As a result, a critical thickness of the continuous film is reduced, but film density is increased. DF-ALD implements an ultra-thin (3 nm) and continuous ruthenium (Ru) film with resistance of about 63 μΩ·cm.

However, the films of the studies using ALD exhibit significantly inferior electrical characteristics including resistivity in comparison to those of the afore-mentioned ruthenium (Ru) thin films produced by PVD. Accordingly, these thin films, when used in actual devices, may deteriorate device quality. A main reason for this is thought to be that ruthenium (Ru) crystal grains included in the thin films are composed of particles with various crystalline facets such as (100), (002), (101), and the like, and in addition, that impurities such as carbon (C), hydrogen (H), and the like are included in the thin films.

Accordingly, research is actively being made to develop a ruthenium (Ru) thin film capable of replacing copper (Cu) and exhibiting lower resistivity, so that it may be used in a wire structure with a narrower line width. However, development of a ruthenium (Ru) thin film, which not only has such a high crystal quality and low resistivity as to be applied to actual devices, but also is manufactured at a low process temperature with a simplified process, has not been made to date.

The present inventors have advantageously developed a ruthenium (Ru) thin film having lower resistivity and exhibiting excellent crystal quality, which is prepared at a low process temperature through a simplified process. The present inventors have confirmed that the film implements low resistivity and thus excellent electrical characteristics in a wire with a narrow line width, for example, a line width of less than or equal to about 10 nm, less than or equal to about 5 nm, and less than or equal to about 3 nm, and as low as 1 nm. Accordingly, embodiments of the present disclosure provide a metallic structure including the ruthenium (Ru) thin film, a method of preparing the metallic structure, and an electronic device including the metallic structure.

The metallic structure according to an embodiment includes a ruthenium thin film disposed on an insulation film or a contact metal, wherein the ruthenium thin film has a crystal structure including grains having a (001) orientation, and neighboring or adjacent grains among the grains in the ruthenium thin film have a misorientation angle of less than or equal to about 15° at a grain boundary based on a horizontal direction of the ruthenium thin film.

That is, the ruthenium thin film included in the metallic structure according to an embodiment not only has excellent orientation in the direction perpendicular to the thin film by including grains having a (001) orientation, but also has a misorientation angle of less than or equal to about 15° at the grain boundary based on the horizontal direction of the thin film, so that the horizontal orientation of the thin film is also improved. Therefore, the ruthenium thin film included in the metallic structure according to an embodiment is a high-quality ruthenium crystalline thin film having excellent crystallinity in both vertical and horizontal directions.

The ruthenium thin film having a (001) orientation may be confirmed from the observation that peaks observed in the upper portion of the thin film by X-ray diffraction (XRD) analysis include peaks in the (002) direction and almost no peaks in the (100) or (101) direction. The vertical crystal orientation of the ruthenium thin film included in the metallic structure according to an embodiment may be compared with the vertical crystal orientation of the ruthenium thin film prepared by the ALD method described above, and as further described below.

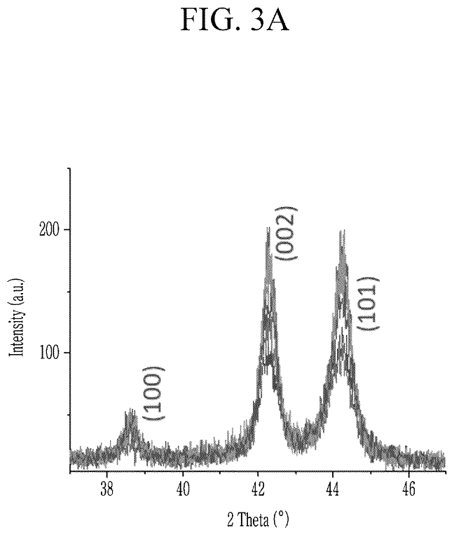

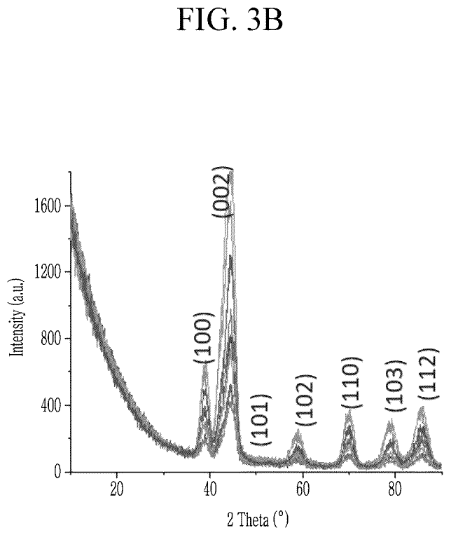

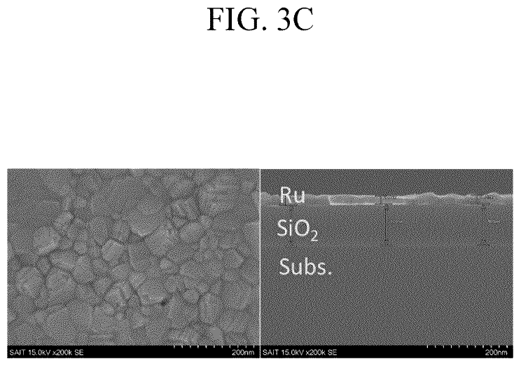

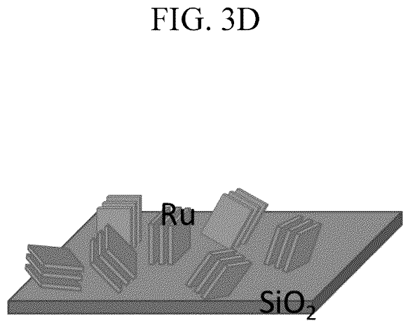

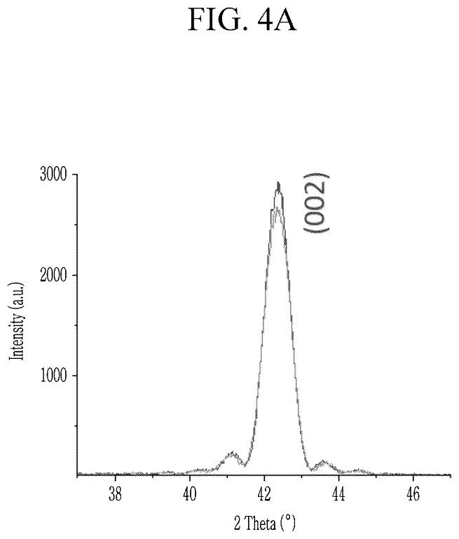

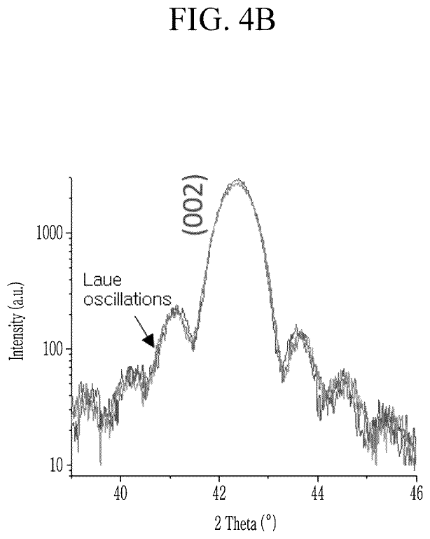

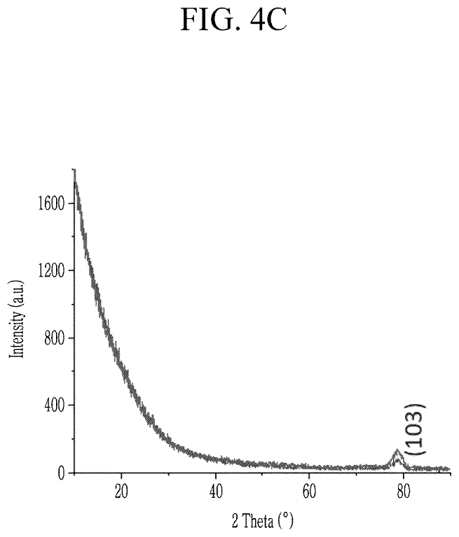

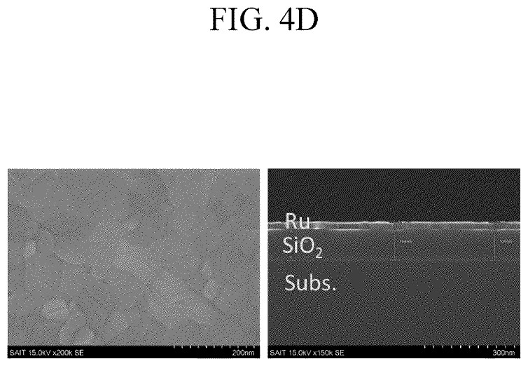

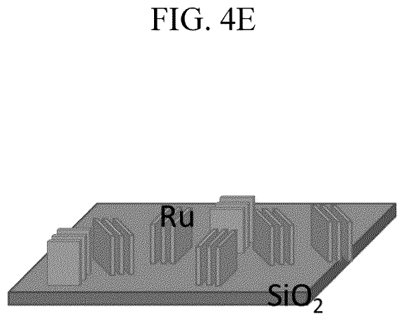

Specifically, FIGS. 3A and 3B are XRD normal mode (A) and glancing angle XRD (B) graphs of a ruthenium thin film prepared by the conventional ALD method described above, and FIGS. 4A, 4B, and 4C are XRD normal mode (FIGS. 4A and 4B) and glancing angle XRD (FIG. 4C) graphs of a ruthenium thin film in a metallic structure according to an embodiment, respectively.

Referring to FIGS. 3A and 3B, not only is the (002) peak visible, but also the (100) peak and the (101) peak are clearly visible. That is, the ruthenium (Ru) thin film prepared by the existing ALD method contains not only grains in which the crystal direction of the c-axis of Ru is aligned with the vertical direction of the substrate, but also many grains that are tilted from the vertical direction. This can also be confirmed from the image (FIG. 3C) of the surface and cross-section of the Ru thin film measured using an actual scanning electron microscopy (SEM). That is, from the left image (plane image) of FIG. 3C, it can be seen that grains are irregularly arranged on the surface of the thin film, and from the right image (cross-sectional image) of FIG. 3C, it can be seen that the surface of the thin film is not actually flat. This occurs because Ru grains with different crystalline facets have different surface energies, which results in differences in deposition rates. FIG. 3D schematically shows the orientation of crystal grains in a Ru thin film prepared by the conventional ALD method. As shown in FIG. 3D, it can be seen that the crystal grains in the Ru thin film prepared by the conventional ALD method include many grains with an orientation tilted from the vertical direction in addition to grains oriented in the vertical direction.

In contrast, referring to FIGS. 4A to 4C, the Ru thin film in the metallic structure according to an embodiment advantageously exhibits only a dominant (002) peak in both the XRD normal mode (FIGS. 4A and 4B) and the glancing angle XRD (FIG. 4C), and no (100) or (101) peak appears at all. This can also be confirmed from the SEM images (FIG. 4D) of the surface and cross-section of the Ru thin film. The left image of FIG. 4D is a surface image of the thin film. The surface of the thin film appears much flatter than the left image of FIG. 3C, and the right image of FIG. 4D also shows that the surface of the Ru thin film is very flat. FIG. 4E schematically illustrates the orientation of crystal grains in a Ru thin film according to an embodiment of the present invention. That is, as shown in FIG. 4E, all crystal grains included in the Ru thin film in the metallic structure according to an embodiment are oriented in the vertical direction, and there are almost no grains tilted from the vertical direction.

Additionally, FIG. 4B shows the graph of FIG. 4A in a semi-log scale, confirming that Laue oscillations appear on the left and right of the (002) peak. The presence of Laue vibrations around the (002) peak indicates that the thin film has a flat surface, i.e., epi-like, similar to crystalline growth. In addition, from the glancing angle XRD results of FIG. 4C, the Ru thin film exhibits a strong orientation in the (001) direction, and thus, unlike FIG. 3B, no XRD peaks are observed. In FIG. 4C, the (103) peak is an XRD peak observed when the X-ray incident angle (omega, ω) is very small, such as 0.5°, and Ru has a (001) aggregate structure.

Therefore, the vertical orientation of the crystal grains in the Ru thin film included in the metallic structure according to an embodiment is excellent.

Thus, for example, a Ru thin film included in a metallic structure according to an embodiment may have a ratio {(002)/(101)} of an intensity of a (002) peak to an intensity of a (101) peak observed by X-ray diffraction (XRD) analysis of greater than or equal to about 30, for example, greater than or equal to about 35, for example, greater than or equal to about 37, for example, greater than or equal to about 38, for example, greater than or equal to about 39, or for example, greater than or equal to about 40, and this ratio of peak intensities means that the Ru thin film does not substantially include a (100) or (101) peak.

Alternatively, the Ru thin film may have a Rotgering degree of orientation about the (002) plane of greater than or equal to about 99%, for example, greater than or equal to about 99.5%, for example, greater than or equal to about 99.9%, for example, 100%, as observed by XRD analysis.

That is, the Ru thin film included in the metallic structure according to an embodiment may have a thin film surface that substantially exhibits a (001) orientation. This means that the vertical orientation of the thin film is excellent.

In addition, it can be confirmed that the Ru thin film included in the metallic structure according to an embodiment has excellent orientation in both the vertical direction and the horizontal direction, as compared to the Ru thin film prepared by the existing sputtering method.

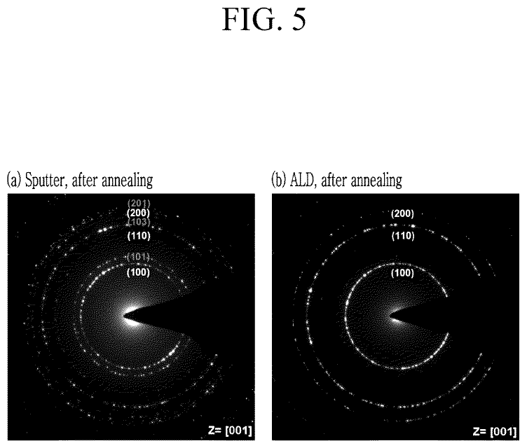

Specifically, (a) and (b) of FIG. 5 are selected area electron diffraction (SAED) patterns measured by transmission electron microscopy (TEM) of a Ru thin film formed by conventional sputtering and thermal curing, and a Ru thin film in a metallic structure according to an embodiment, respectively. Referring to (a) of FIG. 5, the Ru thin film formed by conventional sputtering and thermal curing includes not only crystalline facets {(100), (110), (200)} that form a 90° angle with the c-axis of the Ru crystal in the vertical direction, but also crystalline facets {(101), (103), (201)} that do not form a 90° angle with the c-axis. In contrast, referring to (b) of FIG. 5, the Ru thin film in the metallic structure according to an embodiment contains only crystalline facets {(100), (110), (200)} forming a 90° angle with the c-axis. From this, it can be confirmed that the Ru thin film in the metallic structure according to an embodiment has a much better vertical crystal orientation than the Ru thin film prepared by conventional sputtering and thermal curing.

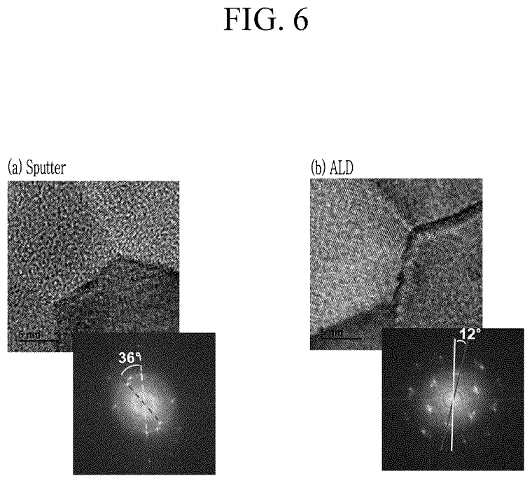

In addition, (a) and (b) of FIG. 6 are high-resolution transmission electron microscope (HRTEM) images and fast Fourier transform (FFT) image obtained therefrom of a Ru thin film formed by the conventional sputtering and thermal curing, and a Ru thin film in a metallic structure according to an embodiment, respectively. That is, the images are obtained by measuring HRTEM images between four adjacent Ru grains in each thin film and measuring the misorientation angles of the grain boundaries by FFT conversion.

Referring to (a) of FIG. 6, the crystal grains in the Ru thin film formed by conventional sputtering and thermal curing have a horizontal misorientation angle of 36° at the boundaries between neighboring grains, and no 6-fold rotation symmetry pattern is observed in the diffraction pattern. This means that the c-axis of the Ru crystal is not parallel to the vertical direction of the substrate, meaning that the inter-grain tilt angle is greatly twisted. In contrast, referring to (b) of FIG. 6, the Ru thin film included in the metallic structure according to an embodiment advantageously has a horizontal misorientation angle of only about 12° at the grain boundaries between neighboring grains within the thin film. From these results, the Ru thin film included in the metallic structure according to an embodiment also has excellent horizontal orientation.

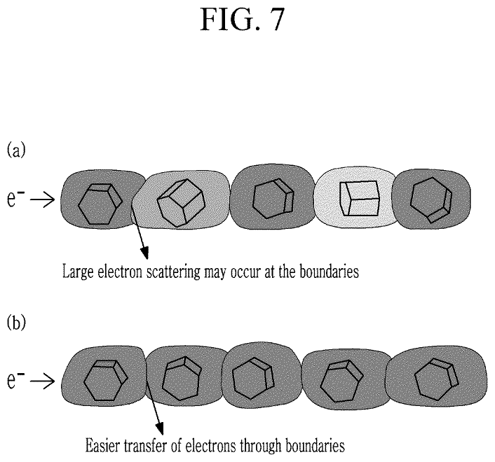

FIG. 7 is a schematic view showing the case where the metal crystal grains forming a narrow-width wire have a strong vertical orientation but inferior horizontal orientation (a), and the case where both the vertical and horizontal orientations are excellent (b). In such cases, due to the narrow line width, the wire is generally composed of a serial arrangement of metal crystal grains. Therefore, the influence of surface scattering and grain boundary (GB) scattering at the surface and boundary of the metal grains can directly affect the electronic device.

In the case of (a) of FIG. 7, when electrons move in a horizontal direction with respect to the thin film, that is, when electrons move in the in-plane direction of the thin film, large electron scattering may occur at the boundaries of the grains, and in this case, the resistivity of the thin film may increase.

Conversely, as in (b) of FIG. 7, when the angle of misorientation at the boundaries between adjacent grains relative to the horizontal direction of the thin film is not large and excellent orientation is exhibited, electron transfer in the in-plane direction of the thin film becomes easy, and accordingly, the increase in resistivity of the thin film may not be large.

That is, it is thought that the Ru thin film included in the metallic structure according to an embodiment will be able to implement low resistivity and excellent electrical characteristics because it has excellent orientation in the horizontal direction, as well as the vertical direction.

Accordingly, the Ru thin film included in the metallic structure according to an embodiment can have a resistivity of less than or equal to about 10 μΩ·cm, for example, less than or equal to about 9.5 cm, at a thickness of 10 nanometers (nm), a resistivity of less than or equal to about 11 μΩ·cm, for example, less than or equal to about 10.9 μΩ·cm, at a thickness of 7 nm, a resistivity of less than or equal to about 13 μΩ·cm, for example, less than or equal to about 12.9 μΩ·cm, at a thickness of 5.2 nm, or a resistivity of less than or equal to about 20 μΩ·cm, for example, less than or equal to about 19.05 μΩ·cm, at a thickness of 3.1 nm.

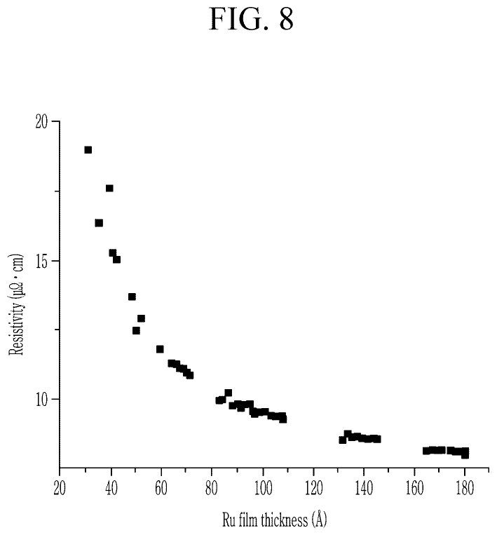

The change in resistivity according to the thickness of the Ru thin film included in the metallic structure according to an embodiment is shown in the graph of FIG. 8.

The resistivity characteristics of the Ru thin film included in the metallic structure according to the above-described embodiment may be similar to or superior to the resistivity characteristics of the conventional Ru thin film deposited by PVD at a temperature of greater than or equal to about 900° C. In the case of implementing a metal wire with a small line width based on a Ru thin film included in a metallic structure according to an embodiment, in which the vertical (001) orientation is strong as shown in (b) of FIG. 7 and only a small misorientation angle exists between adjacent grains in the horizontal direction, smoother passage of electrons at the grain boundaries can be expected compared to the case of using a conventional Ru thin film. Thus low resistivity characteristics can be implemented.

In a metallic structure according to an embodiment, the insulation film may include any dielectric film including aluminum oxide (AlO_{z}, 0<z≤3/2), aluminum nitride (AlN), zirconium oxide (ZrOₓ) (0<x≤2), hafnium oxide (HfOₓ) (0<x≤2), silicon oxide (SiO₂), silicon nitride (SiN), silicon oxynitride (SiON), silicon carbonitride (SiCN), silicon carbonate nitride (SiCON), or a combination thereof, but is not limited thereto. For example, the insulation film may include silicon oxide (SiO₂), silicon nitride (SiN), silicon oxynitride (SiON), silicon carbonitride (SiCN), silicon carbonitride (SiCON), or a combination thereof, and for example, the insulation film may include silicon oxide (SiO₂), silicon nitride (SiN), silicon oxynitride (SiON), or a combination thereof.

In the metallic structure according to an embodiment, the contact metal may include, for example, copper (Cu), aluminum (Al), ruthenium (Ru), cobalt (Co), tungsten (W), molybdenum (Mo), or a combination or an alloy thereof, but is not limited thereto. For example, the contact metal may include various types of metals, either singly or in an alloy state, that can be used as contact metals in various electronic devices. For example, the contact metal may include copper (Cu), aluminum (Al), ruthenium (Ru), or an alloy thereof.

The metallic structure may further include a deposition-inhibiting layer, a barrier layer, a liner layer, or a combination thereof, as needed, between the insulation film and the ruthenium thin film. The deposition-inhibiting layer, barrier layer, or liner layer may be prepared from a variety of materials conventionally used to prepare these deposition-inhibiting layers, barrier layers, or liner layers.

The barrier layer may prevent ruthenium crystal grains in a ruthenium thin film forming a metallic structure according to an embodiment from diffusing into an insulation film. The barrier layer may have a single-layer structure or a multi-layer structure in which multiple layers including different materials are stacked. The barrier layer may include a metal, an alloy of a metal, a metal oxide, a metal nitride, or a combination thereof.

For example, the metal that is usable in the barrier layer may be magnesium (Mg), aluminum (Al), scandium (Sc), titanium (Ti), vanadium (V), chromium (Cr), manganese (Mn), nickel (Ni), zinc (Zn), gallium (Ga), zirconium (Zr), niobium (Nb), molybdenum (Mo), lead (Pd), silver (Ag), cadmium (Cd), indium (In), tin (Sn), lanthanum (La), hafnium (Hf), tantalum (Ta), tungsten (W), iridium (Ir), platinum (Pt), gold (Au), bismuth (Bi), cobalt (Co), ruthenium (Ru), or a combination thereof. The metal alloy of the barrier layer may include ruthenium tantalum (RuTa), or iridium tantalum (IrTa).

The metal oxide of the barrier layer may include a compound represented by Chemical Formula 1:

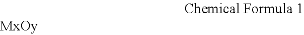

and in Chemical Formula 1,
M may be at least one of manganese (Mn), aluminum (Al), titanium (Ti), zirconium (Zr), hafnium (Hf), magnesium (Mg), silicon (Si), germanium (Ge), yttrium (Y), ruthenium (Lu), lanthanum (La), tantalum (Ta), or strontium (Sr), 0<x≤2, and 0<y≤3.

Examples of the metal oxide may include, for example, MnO, AlOz (0<z≤3/2), TaO_{z} (0<z≤5/2), TiO₂, ZrO₂, HfO₂, MgO, SiO₂, GeO₂, Y₂O₃, Lu₂O₃, La₂O₃, SrO, and the like.

The metal nitride of the barrier layer may include tantalum nitride (TaN), titanium nitride (TiN), ruthenium nitride (RuN), tungsten nitride (WN), aluminum nitride (AlN), iridium tantalum nitride (IrTaN), titanium silicon nitride (TiSiN), and the like.

The liner layer may include a metal, a metal alloy, a metal nitride, or the like. For example, the liner layer may include, tantalum (Ta), titanium (Ti), cobalt (Co), thallium nitride (TaN), titanium (silicon) nitride (Ti(Si)N), or tungsten (W), but is not limited thereto.

The liner layer may include a single-layer structure or a multi-layer structure in which different materials are laminated.

The deposition-inhibiting layer (inhibitor) may include, for example, a material that, when forming a trench within an insulation film and depositing a ruthenium thin film to form a metallic structure according to an embodiment within the trench, is well deposited on the insulation layer forming a side of the insulation film, but is not well deposited on the insulation layer located at the bottom of the trench or on the contact metal. Examples of the material capable of forming the deposition-inhibiting layer include, for example, various silane compounds, siloxanes, silazane compounds, or a combination thereof.

For example, the silane compounds capable of forming the deposition-inhibiting layer may include alkyl silane, alkoxysilane, alkyl alkoxysilane, aryl silane, acyl silane, or the like, and the siloxane may include alkyl siloxane, alkoxysiloxane, alkyl alkoxysiloxane, aryl siloxane, acyl siloxane, and the like. In the foregoing silane and siloxane compounds, the alkyl and alkoxy groups can each independently have, for example, 1 to 12 carbon atoms, the acyl groups can have, for example, from 2 to 12 carbon atoms, and the aryl groups can have 6 to 18 carbon atoms. Specific examples of the silane compound may include those having one or more monoalkylamino or dialkylamino groups, for example tris(dimethylamino)methylsilane (TDMAMS), bis(N,N-dimethylamino)-dimethylsilane (DMADMS), dimethylamino-trimethylsilane (DMATMS), (DMSDMA), trimethylsilane dimethylamine dimethylsilane dimethylamine (TMSDMA), bis(dimethylamino) dimethylsilane (BDMADMS), as well as compounds such as N,O bistrimethylsilyltrifluoroacetamide (BSTFA), trimethylsilyl-pyrrole (TMS-pyrrole), or a mixture thereof, but are not limited thereto.

The barrier layer, liner layer, and deposition-inhibiting layer may each independently be formed through various deposition processes, including chemical vapor deposition (CVD), plasma-enhanced chemical vapor deposition (PECVD), physical vapor deposition (PVD), atomic layer deposition (ALD), sputtering, or a plating method (electroplating), which are used in general semiconductor manufacturing processes.

Next, a method of preparing a metallic structure according to an embodiment is described.

A method of preparing a metallic structure according to an embodiment may include depositing a precursor comprising ruthenium on an insulation film or a contact metal, together with an oxidizing agent, a reducing agent, or a combination thereof, at a process pressure of less than or equal to about 10 Torr and a process temperature of less than or equal to about 550° C., for example less than or equal to about 500° C., or less than or equal to about 450° C. by an atomic layer deposition (ALD) or chemical vapor deposition (CVD) method to form the afore-mentioned ruthenium thin film.

That is, the ruthenium thin film to be deposited has a crystal structure including grains having a (001) orientation, and neighboring or adjacent grains among the grains may have a misorientation angle of less than or equal to about 15°, for example, a misorientation angle of less than or equal to about 12°, for example, a misorientation angle of less than or equal to about 10°, at the grain boundary based on the horizontal direction of the thin film.

As the precursor containing the ruthenium, various types of ruthenium-containing compounds known in the art may be used. Examples of the ruthenium-containing compound may include a ruthenium-containing compound represented by (arene)(diene)Ru(0), (arene)(triene)Ru(0), (diene)(CO)₃Ru(0), (triene)(CO)₃Ru(0), (cyclopentadienyl)(CO)₂(R)Ru(II), (cyclopentadienyl)₂Ru(II), (pentadienyl)(η⁵-cyclopentadienyl)Ru(II), (pentadienyl)₂Ru(II), (diketonate)₂(CO)₂Ru(II), or (amidinate)₂(CO)₂Ru(II).

For example, the compound represented by the (arene)(diene) Ru(0) may include (ethylbenzene)(1-ethyl-1,4-cyclohexadiene)Ru(0), (1-isopropyl-4-methylbenzene)(1,3-cyclohexadiene)Ru(0), or the like, the compound represented by the (arene)(triene)Ru(0) may include (benzene)(1,3,5-cycloheptatriene)Ru(0), the compound represented by the (diene)(CO)₃Ru(0) may include (2,3-dimethyl-1,3-butadieneL)Ru(0) tricarbonyl, (1,3-cyclohexadiene)Ru(0)tricarbonyl, or the like, the compound represented by the (triene)(CO)₃Ru(0) may include (1,3,5-cycloheptatriene)Ru(0) tricarbonyl, and the compound represented by (cyclopentadienyl)(CO)₂(R)Ru(II) may include (cyclopentadienyl)(ethyl)Ru(II) dicarbonyl, the compound represented by (cyclopentadienyl)₂Ru(II) may include bis(ethylcyclopentadienyl)Ru(II), the compound represented by (pentadienyl)(η⁵-cyclopentadienyl)Ru(II) may include (2,4-dimethylpentadienyl) (ethylcyclopentadienyl)Ru(II), the compound represented by (pentadienyl)Ru(II) may include bis(2,4-dimethylpentadienyl)Ru(II), the compound represented by (diketonate)₂(CO)₂Ru(II) may include bis (2,4-pentanediketonato)Ru(II)dicarbonyl, and the compound represented by (amidinate)₂(CO)₂Ru(II) may include (N,N′-di-isopropylacetamidinato)Ru(II)dicarbonyl.

In an embodiment, the ruthenium-containing precursor may include (tricarbonyl(trimethylenemethane)ruthenium [Ru(TMM)(CO)₃], bis(ethylcyclopentadienyl)ruthenium(II) [Ru(EtCp)₂], bis(2,4-dimethylpentadienyl)ruthenium(II) [Ru(DMPD)₂], dicarbonyl-bis(5-methyl-2,4-hexanediketonato)ruthenium(II) [carish], (1,3-cyclohexadiene)(ethylbenzene)ruthenium(0) [EBCHDRu], or a combination thereof, but is not limited thereto.

The oxidizing agent may include plasma species generated from oxygen (O₂), ozone (O₃), water (H₂O), or a combination thereof.

The reducing agent may include plasma species generated from hydrogen (H₂), ammonia (NH₃), or a combination thereof.

The method of preparing the metallic structure may further include patterning the deposited ruthenium thin film after depositing the ruthenium thin film.

In addition, after depositing the ruthenium thin film, the method may further include forming an upper electrode including upper metal wires on the deposited ruthenium thin film.

In addition, the method of preparing the metallic structure may further include forming an additional insulation film including a trench on the insulation film or contact metal before the depositing of the ruthenium thin film. Additionally, after forming the trench, a barrier layer, a liner layer, a deposition-inhibiting layer, or a combination thereof may be further formed on the inner surface of the trench, on the upper portion of the insulation film, or on both of them.

The ruthenium thin film may be deposited within a trench formed in the insulation film.

Hereinafter, a method of implementing a metallic structure according to an embodiment of the present disclosure as, for example, an upper via or upper metal wire of a three-dimensional logic device is described.

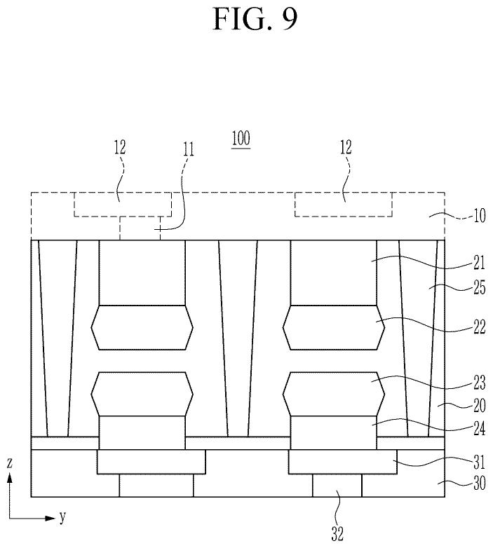

FIG. 9 is a schematic view showing a cross-section of an electronic device implemented with a metallic structure, as indicated by a dotted line, as an upper via or upper metal wire of a three-dimensional logic device, as indicated by a solid line, according to an embodiment.

That is, as indicated by the dotted line in FIG. 9, the metallic structure according to an embodiment may be formed as an upper via 11 or an upper metal wire 12 on the upper portion of the three-dimensional logic device 100 indicated by the solid line. An upper via 11 including a metallic structure according to an embodiment may be formed on an upper contact metal 21 formed within an intermediate insulation layer 20, and an upper metal wire 12 including a metallic structure according to an embodiment may be additionally formed on the upper via 11.

An upper source or drain element 22 is disposed under an upper contact metal 21 in an intermediate insulation layer 20, a lower source or drain element 23 is disposed facing the upper source or drain element 22 with the intermediate insulation layer 20 interposed therebetween, and a lower contact metal 24 is disposed under the lower source or drain element 23.

The lower contact metal 24 is in contact with the lower via 31 formed in the lower insulation layer 30 formed under the intermediate insulation layer 20, and the lower metal wire 32 may be disposed under the lower via 31.

A through contact 25 that connects metal wire formed on the upper insulation layer 10 and the lower insulation layer 30 may be formed in the intermediate insulation layer 20.

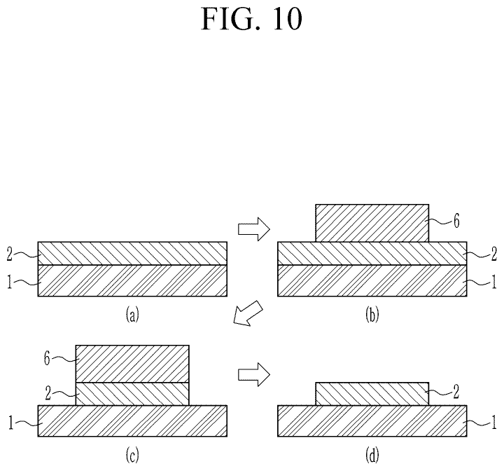

FIG. 10 is a view schematically showing a method for forming an upper via 11 or upper metal wire 12 shown in FIG. 9.

As shown in (a) of FIG. 10, a Ru thin film 2 forming a metallic structure according to an embodiment is deposited on an insulation film such as SiO₂ or on the upper portion of a contact metal 1 as described above. The method for depositing the Ru thin film 2 may be performed by depositing a precursor including Ru as described above together with a coreactant such as a reducing gas such as H₂ or an oxidizing gas such as O₂ by ALD or CVD.

As an example of the Ru thin film 2, when using ALD, after setting a partial pressure of oxidizing agent gas (a partial pressure ratio of oxidizing agent/N₂ or oxidizing agent/Ar) within a range of from about 1 to about 0.05 under a process pressure of about less than or equal to about 10 Torr, a Ru-containing precursor may be discontinuously injected at a frequency of 1 to 4 times in an one-cycle process to deposit the Ru thin film 2 at a process temperature of less than or equal to about 550° C., for example, less than or equal to about 500° C., for example, less than or equal to about 450° C. In addition, after depositing the Ru thin film, a post-annealing process may be performed to additionally adjust crystalline orientation of the thin film particles. The post-annealing process also may be performed at less than or equal to about 550° C., for example, less than or equal to about 500° C., or for example, less than or equal to about 450° C.

After forming the Ru thin film 2, as shown in (b) of FIG. 10, an etching mask 6 is formed on the Ru thin film 2 through photography and an etching process.

Subsequently, as shown in (c) of FIG. 10, the Ru thin film 2 is patterned according to a pattern of the etching mask 6 through a dry etching process.

Then, as shown in (d) of FIG. 10, the etching mask 6 may be removed to realize an upper via metallic structure or an upper metal wire of the Ru thin film 2 patterned into a desired shape.

Optionally, an upper electrode including upper metal lines may be additionally formed on the manufactured upper via or upper metal wire as needed.

As a further embodiment, another method of implementing a metallic structure according to an embodiment as an upper via or upper metal wire of a three-dimensional logic device is described.

In FIG. 9, the upper layer where the upper via 11 or upper metal wire 12 of the three-dimensional logic device 100 is formed may also be formed of an insulation layer 10. In this case, the insulation layer 10 may be formed in advance to form a space, for example, a trench structure, in which an upper via 11 or an upper metal wire 12 is to be formed.

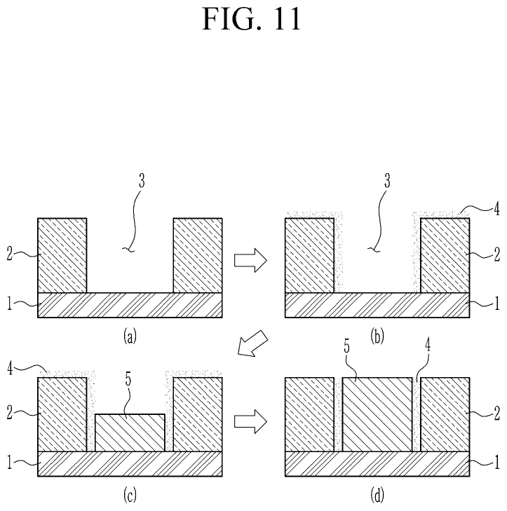

FIG. 11 is a drawing schematically showing a method of first forming the insulation layer 10 in the upper layer of the logic device, and then, forming the upper via 11 or the upper metal wire 12 in a trench in the insulation layer 10, as depicted in FIG. 9.

As shown in (a) of FIG. 11, an insulation film 2 is formed by using SiO₂ and the like on a lower insulation layer or contact metal 1. Here, in the insulation film 2, a trench 3 where a via will be formed is formed.

Subsequently, as shown in (b) of FIG. 11, a deposition-inhibiting layer (inhibitor) 4 may be formed selectively on the inner surface of the trench 3 and on top of the insulation film 2. The deposition-inhibiting layer 4 may be formed by depositing a material composed of a silane compound, a siloxane compound, a silazane compound, or a combination thereof on the inner surface of the trench 3 and on top of the insulation film 2. The materials forming the deposition-inhibiting layer 4 and the method of forming the deposition-inhibiting layer 4 are the same as described above.

Subsequently, as shown in (c) of FIG. 11, a metal via 5 is formed by depositing a Ru thin film inside the trench 3 where the deposition-inhibiting barrier layer 4 is formed through the same ALD method as illustrated in FIG. 10.

Then, as shown in (d) of FIG. 11, the deposition-inhibiting layer 4 formed on top of the insulation film 2 is removed.

In addition, if desired, an upper electrode including upper metal lines may be additionally formed on top of the metal via 5.

In the above, the formation of the deposition-inhibiting layer 4 inside the trench 3 is exemplarily described but may not be necessarily required and may be omitted or excluded depending on the particular case or application. In addition to the deposition-inhibiting layer 4, if desired, a barrier layer and/or a liner layer may optionally be further formed.

In addition to the method of forming the metallic structure according to an embodiment indicated by a dotted line in the logic device 100 of FIG. 9, that is, the upper via 11 or the upper metal wire 12, the remaining part indicated by a solid line may be manufactured identically or similarly by methods and materials for manufacturing general 3-dimensional logic devices.

Hereinbefore, the method of forming a metal via or an upper metal wire by using the metallic structure according to an embodiment is illustrated, which exemplarily illustrates an embodiment, but is understood not to limit the scope of the present invention. For example, the metallic structure according to an embodiment may be advantageously used in any product to which ruthenium thin films may be applied in memory or non-memory devices.

Although the embodiments have been described in detail above, the scope of the present invention is not limited to these, and various modifications and improvements made by those skilled in the art using the basic concepts defined in the claims below also fall within the scope of the present invention.

What is claimed is:

1. A metallic structure comprising:
a ruthenium thin film disposed on an insulation film or a contact metal,
wherein the ruthenium thin film has a crystal structure comprising grains having a (001) orientation, and neighboring grains among the grains in the ruthenium thin film have a misorientation angle of less than or equal to about 15° at a grain boundary based on a horizontal direction of the ruthenium thin film,
thereby forming the metallic structure.

2. The metallic structure of claim 1, wherein the ruthenium thin film has a ratio {(002)/(101)} of an intensity of a (002) peak to an intensity of a (101) peak observed by X-ray diffraction analysis of greater than or equal to about 30.

3. The metallic structure of claim 1, wherein the ruthenium thin film has a Rotgering degree of orientation of greater than or equal to about 99% for a (002) plane as observed by X-ray diffraction analysis.

4. The metallic structure of claim 1, wherein the ruthenium thin film has a resistivity of less than or equal to about 10 microohm-centimeter at a thickness of 10 nanometers.

5. The metallic structure of claim 1, wherein the insulation layer comprises aluminum oxide, aluminum nitride, zirconium oxide, hafnium oxide, silicon oxide, silicon nitride, silicon oxynitride, silicon carbonitride, silicon carbonate nitride, or a combination thereof.

6. The metallic structure of claim 1, wherein the contact metal comprises copper, aluminum, ruthenium, cobalt, tungsten, molybdenum, or a combination thereof.

7. The metallic structure of claim 1, wherein the metallic structure further comprises a deposition-inhibiting layer, a barrier layer, a liner layer, or a combination thereof between the insulation film and the ruthenium thin film.

8. A method of preparing a metallic structure, comprising:
depositing a precursor comprising ruthenium on an insulation film or a contact metal, together with an oxidizing agent, a reducing agent, or a combination thereof, at a process pressure of less than or equal to about 10 Torr and a process temperature of less than or equal to about 550° C. by an atomic layer deposition or chemical vapor deposition method to form a ruthenium thin film,
wherein the formed ruthenium thin film has a crystal structure comprising grains having a (001) orientation, and neighboring grains among the grains in the ruthenium thin film have a misorientation angle of less than or equal to about 15° at the grain boundary based on a horizontal direction of the ruthenium thin film,
thereby forming the metallic structure.

9. The method of claim 8, wherein the process temperature is less than or equal to about 450° C.

10. The method of claim 8, wherein the precursor comprising ruthenium comprises (ethylbenzene)(1-ethyl-1,4-cyclohexadiene)Ru(0), (1-isopropyl-4-methylbenzene)(1,3-cyclohexadiene)Ru(0), (benzene)(1,3,5-cycloheptatriene)Ru(0), (2,3-dimethyl-1,3-butadieneL)Ru(0)tricarbonyl, (1,3-cyclohexadiene)Ru(0)tricarbonyl, (1,3,5-cycloheptatriene)Ru(0)tricarbonyl, (cyclopentadienyl)(ethyl)Ru(II)dicarbonyl, bis(ethylcyclopentadienyl)Ru(II), (2,4-dimethylpentadienyl)(ethylcyclopentadienyl)Ru(II), bis(2,4-dimethylpentadienyl)Ru(II), bis(2,4-pentanediketonato)Ru(II)dicarbonyl, (N,N′-di-isopropylacetamidinato)Ru(II)dicarbonyl, or a combination thereof.

11. The method of claim 8, wherein the oxidizing agent comprises a plasma species generated from oxygen, ozone, water, or a combination thereof.

12. The method of claim 8, wherein the reducing agent comprises a plasma species generated from hydrogen, ammonia, or a combination thereof.

13. The method of claim 8, wherein the method further comprises annealing at a temperature of less than or equal to about 550° C. after depositing the ruthenium thin film.

14. The method of claim 8, wherein the method further comprises patterning the formed ruthenium thin film after forming the ruthenium thin film.

15. The method of claim 8, wherein the method further comprises forming an upper electrode on the formed ruthenium thin film.

16. The method of claim 8, wherein the method further comprises forming an additional insulation film comprising a trench on the insulation film or contact metal before the depositing of the ruthenium thin film.

17. The method of claim 16, wherein the method further comprises forming a deposition-inhibiting layer, a barrier layer, a liner layer, or a combination thereof on an inner surface of the trench, on an upper portion of the additional insulation film, or on both of the inner surface of the trench and the upper portion of the additional insulation film, after forming the trench and before the depositing of the ruthenium thin film.

18. The method of claim 16, wherein the ruthenium thin film is deposited within the trench.

19. An electronic device comprising the metallic structure according to claim 1.

20. The electronic device of claim 19, wherein the electronic device comprises a logic device, a memory device, or a non-memory device.
